(19) United States
(12) Patent Application Publication
(10) Pub. No.: US 2010/0224231 A1
(43) Pub. Date: Sep. 9, 2010

(54) Photovoltaic Module Utilizing Beam Steering and a Fixed Concentrator

(76) Inventor: Charles D. Hoke, Menlo park, CA (US)

Correspondence Address: THE LAW OFFICES OF CALVIN B. WARD, 18 CROW CANYON COURT, SUITE 305, SAN RAMON, CA, 94583, US

(21) Appl. No.: 12/717,889

(22) Filed: Mar. 4, 2010

Related U.S. Application Data
(60) Provisional application No. 61/158,265, filed on Mar. 6, 2009.

(51) Int. Cl. H01L 31/052

(52) U.S. Cl. 136/246

(57) ABSTRACT

A solar power apparatus and method for fabricating the same are disclosed. The apparatus includes a beam steering assembly, a plurality of converts, and a controller. The beam steering assembly directs light traveling in a first direction to light traveling in a second direction. Each converter is fixed with respect to a substrate, and each converter includes a light concentrator and a receiver. The controller determines the position of the sun relative to the beam steering assembly and controls the beam steering assembly such that the concentrators receive sunlight from that determined direction. Each light concentrator is fixed relative to the light receiver that receives light from that light concentrator. The beam steering assembly elements can be fabricated by molding or by embossing of thin plastic sheets.

### RELATED APPLICATION

The present application claims priority from U.S. Provisional Application Ser. No. 61/158,265 filed on Mar. 6, 2009, entitled “Rotary Solar Concentrator for Photovoltaic Modules” which is incorporated herein by reference in its entirety.

### BACKGROUND OF THE INVENTION

The simplest photovoltaic (PV) power generators are constructed from flat plate solar collectors in the form of flat panels that are mounted in a fixed relationship to the sun. The panels are often mounted on the roof of a structure on the property at which a significant fraction of the power generated by the panels is utilized. Such panels require the least amount of maintenance, and hence, are attractive candidates for rooftop installations on residences. Such installations utilize the existing power grid to distribute the energy that is not utilized at the residence. Hence, the need for improvements in transmission systems is substantially reduced. Furthermore, this type of installation is exempt from most current environmental regulatory schemes, and hence, the cost and delays inherent in obtaining regulatory approval of an installation are avoided.

While the cost per watt of peak generating output has decreased significantly over the last several years, such photovoltaic power generating systems are still significantly more costly than competing power generating technologies. The costs are directly related to the efficiency of the system. The efficiency of power generation is determined by the efficiency with which the photovoltaic cells convert light to electricity and the efficiency with which solar radiation is collected and applied to the PV cells. The efficiency of collection for a fixed collector is poor, since for most of the day, the collector receives light from an oblique angle, and hence, the amount of light that strikes the collector is reduced by the cosine of the angle between the normal to the collector and the angle of the sun with respect to this normal. As a result, the efficiency of collection is reduced by at least a factor of two with respect to collecting light received directly from the sun.

The light collection inefficiency associated with maintaining the collector in a fixed position can be reduced by moving the collector during the day such that the sunlight strikes the collector at normal incidence. However, this solar tracking approach presents challenges from both a cost and maintenance point of view. Collectors are heavy and have a large surface area. Furthermore, collectors are usually mounted in locations that are subjected to significant wind velocities, particularly during storms. Hence, the hardware that supports the collectors must be able to operate with much higher loads than just those associated with the weight of the collectors. Typically, a number of collectors are mounted on a surface that is rotationally mounted on a pole. The pole must be anchored in the ground in a manner that can withstand the forces generated by the wind, and the bearings and motors must be sized to move the panels when the wind is present. As a result, although the cost savings associated with increasing the efficiency of collection are significantly reduced, the maintenance costs are substantially increased. The cost per watt of collector capacity associated with the tracking and mounting systems is a significant fraction of the cost of the collectors that are supported. Hence, the improvements in collection efficiency are offset to large degree by the additional costs of the tracking system. Accordingly, such tracking systems have had only limited success.

The cost of converting light to electricity depends on the degree of concentration of the light on the PV cells. In the simple flat plate collector, the sunlight is not concentrated, and each square meter of PV cell area receives approximately 1000 watts of sunlight at solar noon. The cost of the PV cells is roughly proportional to the area of the PV cells. If the sunlight is collected and concentrated onto the PV cells, a much smaller area of PV cells is needed to convert the same amount of sunlight. In addition, the efficiency of conversion of light to electricity increases as the density of energy on the PV cells increases. Since the cost of a lens, or concentrating mirror, per unit area is much less than the cost of PV cells per unit area, collectors based on lenses, mirrors, or other concentrating elements have been proposed.

While concentrator based systems hold the potential for significant decreases in the cost of PV systems, such systems typically require some form of solar tracking element. For example, in a lens based system, the axis of each lens of the lens array must be maintained in a fixed relationship to the sun as the sun moves across the sky. In the simplest arrangement, the lens array and the PV cells are mounted on a fixed substrate that is rotated in a manner analogous to that discussed above. As noted above, such tracking systems present challenges from a cost point of view.

Systems in which the PV cells and mounting substrate do not move attempt to overcome the problems associated with moving the entire substrate and attached PV cells. In such systems, a beam steering element is placed over the concentrating lens and parallel to the plane of the concentrating lens. By rotating elements in the steering element, the direction of the sun's light is bent from an oblique incidence angle such that the redirected light now strikes the concentrating element at, or near, normal incidence. The beam steering element is constructed from lightweight optical elements that are rotated with respect to one another about an axis that is perpendicular to the substrate on which the PV cells are mounted, and hence, the only mass that needs to be moved is that of these lightweight elements.

While such beam steering systems have the potential to provide a significant improvement in terms of the mass that must be moved to track the sun, the systems are less than optimum for collectors that utilize a large number of PV cells arranged such that each PV cell has its own concentrating lens. These prior art beam steering systems require that multiple beam steering assemblies be independently rotated. The need to provide multiple rotating assemblies significantly complicates the design of such systems and increases the cost.

### SUMMARY OF THE INVENTION

The present invention includes a solar power apparatus and method for fabricating the same. The apparatus includes a beam steering assembly, a plurality of converters, and a controller. The beam steering assembly directs light traveling in a first direction to light traveling in a second direction. Each converter is fixed with respect to a substrate, and each converter includes a light concentrator and a receiver. The light concentrator receives light from the second direction at a first optical power density and generates a light beam on the receiver at a second optical power density that is greater than the first optical power density. The light receiver converts the received light to electricity. The controller determines the position of the sun relative to the beam steering assembly and controls the beam steering assembly such that the concentrators receive sunlight from that determined direction. Each light concentrator is fixed relative to the light receiver that receives light from that light concentrator.

In one aspect of the invention, the beam steering assembly includes first and second beam steering elements, each beam steering element moving relative to the substrate.

In one aspect of the invention, the first and second beam steering elements each include a transparent beam steering sheet having optical processing features thereon. The first and second beam steering elements rotate independently with respect to the substrate about a common axis in response to commands from the controller. In another aspect of the invention, the optical processing features of the beam steering sheet are micro-prisms. In a still further aspect of the invention, at least one of the first and second beam steering sheets has a surface that is textured with an antireflective structure.

A plurality of power modules can be combined into an apparatus in which all of the beam steering assemblies are driven from the same two drive shafts.

The beam steering assembly elements can be fabricated by molding or by embossing of thin plastic sheets on a roll-to-roll fabrication apparatus.

### BRIEF DESCRIPTION OF THE DRAWINGS

FIG. 1 is a schematic cross-sectional view of power photovoltaic module according to one embodiment of the present invention.

FIG. 2A is a top view of one embodiment of a beam steering assembly according to the present invention.

FIG. 2B is a cross-sectional view of beam steering assembly 35.

FIG. 3 is a perspective view of beam steering assembly 54.

FIG. 4 is a cross-sectional view of a portion of beam steering assembly 54 and the underlying light concentrating elements.

FIG. 5 is a top view of array 60.

FIG. 6 is a partial cross-sectional view through line 6-6 shown in FIG. 5.

FIG. 7 is a partial cross-sectional view through line 7-7 shown in FIG. 5.

FIG. 8 is a top view of an array of packaged power modules that utilize hexagonal housings.

FIG. 9 is a cross-sectional view of a power module 90 according to another embodiment of the present invention.

FIG. 10 illustrates a beam steering assembly based on two prisms that are rotated with respect to one another.

FIG. 11 illustrates the manner in which a large prism is broken up into three smaller prisms.

FIG. 12 is a cross-sectional view through a portion of a Fresnel prism array.

### DETAILED DESCRIPTION OF THE PREFERRED EMBODIMENTS OF THE INVENTION

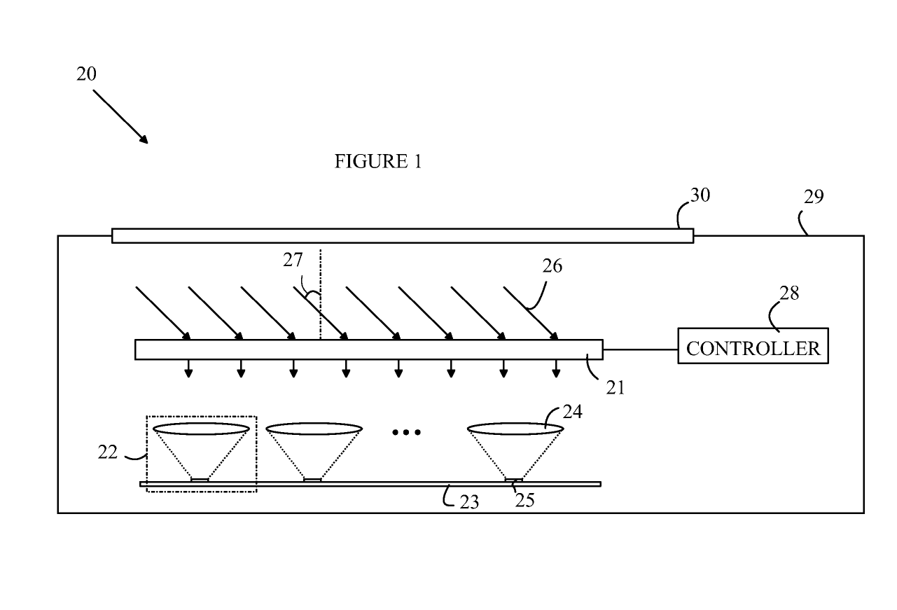

The manner in which the present invention provides its advantages can be more easily understood with reference to FIG. 1, which is a schematic cross-sectional view of power photovoltaic module according to one embodiment of the present invention. Power photovoltaic module 20 includes a plurality of light converters 22 mounted in a fixed relationship to a substrate 23. Each light converter includes a concentrating optical element 24 and a PV cell 25. For convenience, the concentrating elements are shown as lenses; however, it is to be understood that other forms of concentrating elements could be utilized.

Sunlight 26 received by power module 20 is directed toward the concentrators 24 by a steering assembly 21 that rotates the direction of travel of the sunlight from angle 27 to an angle that is substantially normal to the light concentrating elements. The angle through which the sunlight is rotated is determined by the relative position of a set of optical elements that are contained within steering assembly 21. The details of these elements will be discussed below. For the purposes of the present discussion, it is sufficient to note that a controller 28 determines the current position of the sun relative to power module 20 and adjusts the elements so that light leaving beam steering assembly 21 will be concentrated onto PV cells 25.

In one embodiment, the optical elements, including beam steering assembly 21, are contained in a housing 29 having a transparent window 30. Housing 29 protects the optical elements and moving assemblies from the environment and is fixed in place on a roof or other suitable structure. Hence, the only parts that need to move are those in beam steering assembly 21, and, as will be explained below, those elements have a low mass, and hence, the problems associated with moving an entire solar panel are avoided. Finally, as will be explained in more detail below, beam steering assembly 30 can be constructed from only two elements that need to be moved with respect to one another, and hence, the problems associated with steering arrangements that require one moving assembly per converter are avoided.

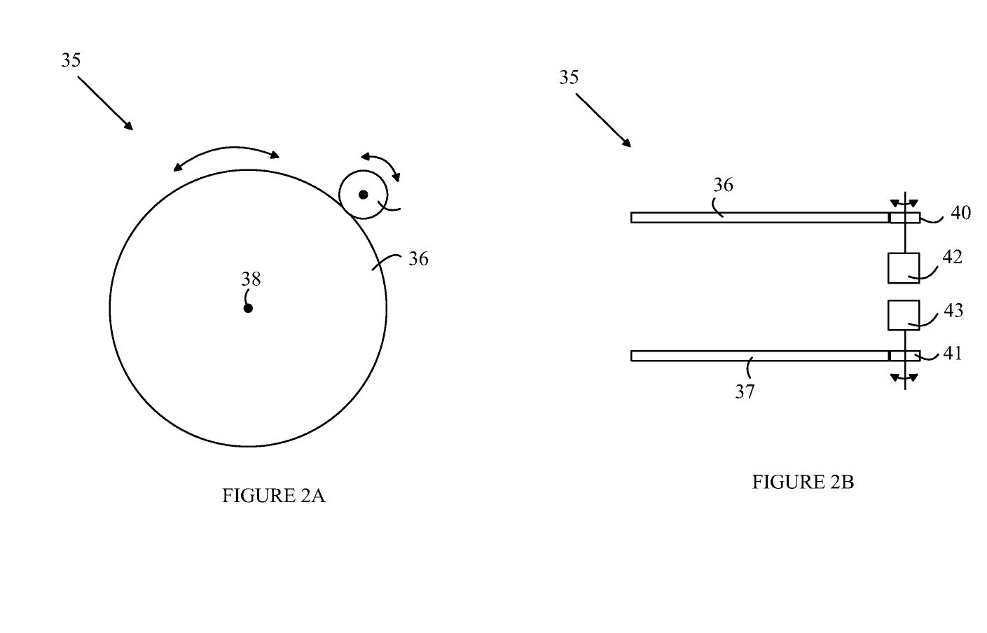

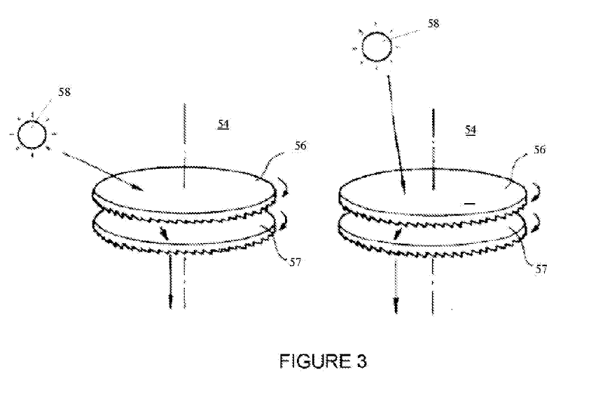

The above-described embodiments utilize a beam steering assembly to alter the angle of the incoming solar radiation. Refer now to FIGS. 2A and 2B, which illustrate one embodiment of a beam steering assembly according to the present invention. FIG. 2A is a top view of one embodiment of a beam steering assembly according to the present invention, and FIG. 2B is a cross-sectional view of beam steering assembly 35. Beam steering assembly 35 is constructed from two thin films 36 and 37 that rotate about a common axis 38. The relative rotational position of the thin films is altered by drive wheels 40 and 41 that are actuated by motors 42 and 43, respectively.

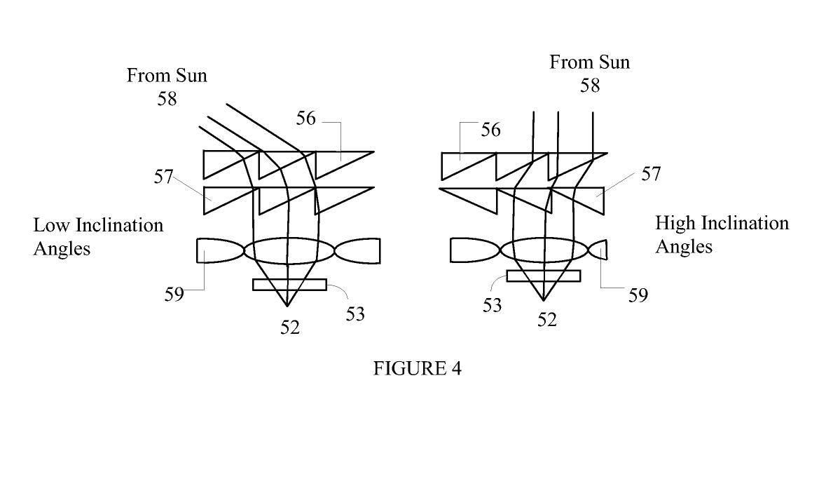

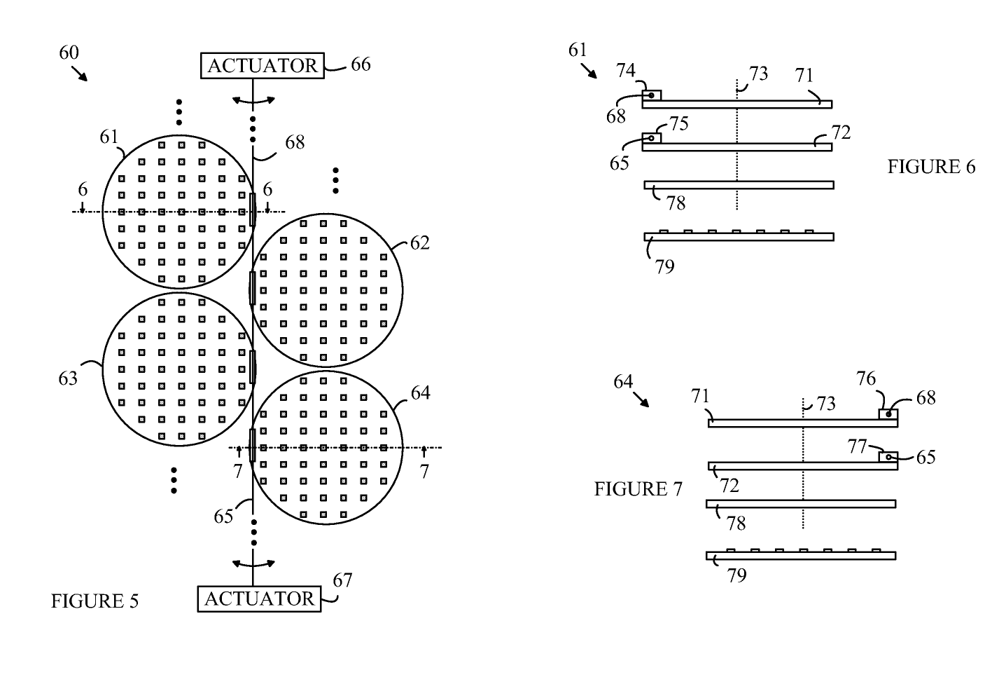

Each of the films includes optical elements that are imprinted onto the films. These optical elements can be prisms or any other optical elements that rotate the direction of travel of light that is processed by the optical elements. Refer now to FIGS. 3 and 4, which illustrate one embodiment of a beam steering assembly that can be utilized in the present invention. FIG. 3 is a perspective view of beam steering assembly 54, and FIG. 4 is a cross-sectional view of a portion of beam steering assembly 54 and the underlying light concentrating elements. Beam steering assembly 54 includes two micro-structured optical film elements 56 and 57, which are aligned one over the other and centered about a common axis of rotation. Each of the beam steering films 56 and 57 includes micro-prism arrays, which refract light rays incident thereon. The two beam steering films are rotatable with respect to one another about a central rotation axis so that as the sun 58 moves relative to a plane defined by a top surface of the concentrator (i.e., from low inclination angles to high inclination angles), one micro-prism array rotates relative to the other so that the incident rays of sunlight are always redirected to a small cone of angles about the axis of rotation. The redirected rays from the beam steering assembly are incident on a Fresnel lens array 59 that focuses the rays to a point 52. The PV cells are placed off of the focal plane of the Fresnel lenses such that the concentrated light illuminates substantially all of the surface of the PV cells 53 at a substantially constant light intensity. Alternatively, a secondary optical element may be mounted to the surface of the PV cell to improve illumination uniformity.

It should be noted that only films 56 and 57 move. The concentrating lens and PV cells remain fixed in space. One pair of rotating films is required per power module independent of the number of concentrator and PV cells in the module. As discussed above, the beam steering elements may be implemented as imposed films, with correspondingly low mass and hence, low energy requirements for their controlled motion.

The films may be created using manufacturing techniques originally introduced in the flat panel display industry. These techniques are able to produce films at relatively low cost by employing roll-to-roll manufacturing processes in which the structures are embossed on planar films. The embossed films are then mounted on a more rigid support. Alternatively, traditional injection/compression molding methods may be used to provide rigid structures with the desired optical processing elements. The concentrators could also be formed in a single sheet in which an array of Fresnel lenses is molded as shown in FIG. 4.

The use of Fresnel lens arrays for solar concentrators is known to the art. In general, the arrays are implemented with the Fresnel grooves on only one side of the sheet and with that side facing down toward the light receiver, in spite of the fact that the opposite orientation, of grooves facing the incident beam, is known to be less prone to focal errors. The less optically-optimum orientation is typically chosen to avoid the effects of dirt accumulation and consequent cleaning-induced surface damage. In the present invention, the Fresnel lens array is located underneath the beam steering elements, which improved protection from dust and dirt from the external environment, and hence, the array may be oriented with the grooved-surface uppermost. Alternately, a sheet with grooved profiles on both surfaces may be used.

Many applications of the present invention will require multiple power modules to provide the level of power needed. There is a practical limit to the size of a power module that is determined by the economics of molding or imprinting the arrays of optical elements. Furthermore, as the size of the steering elements increases, the level of structure needed to support the rotating elements without the elements deforming increases. Accordingly, power module designs that are adapted to being assembled into arrays of power modules are preferred.

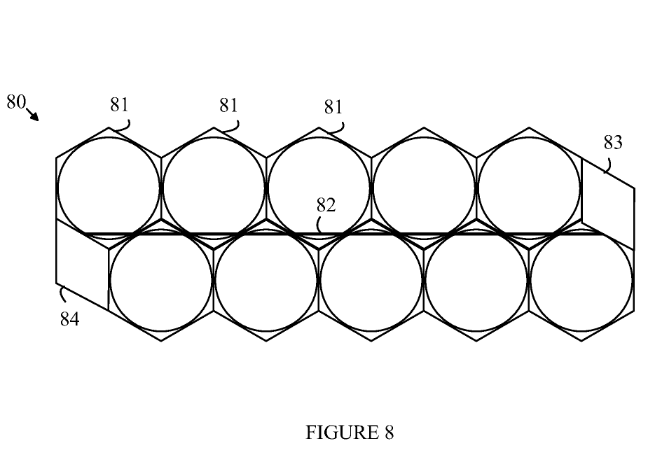

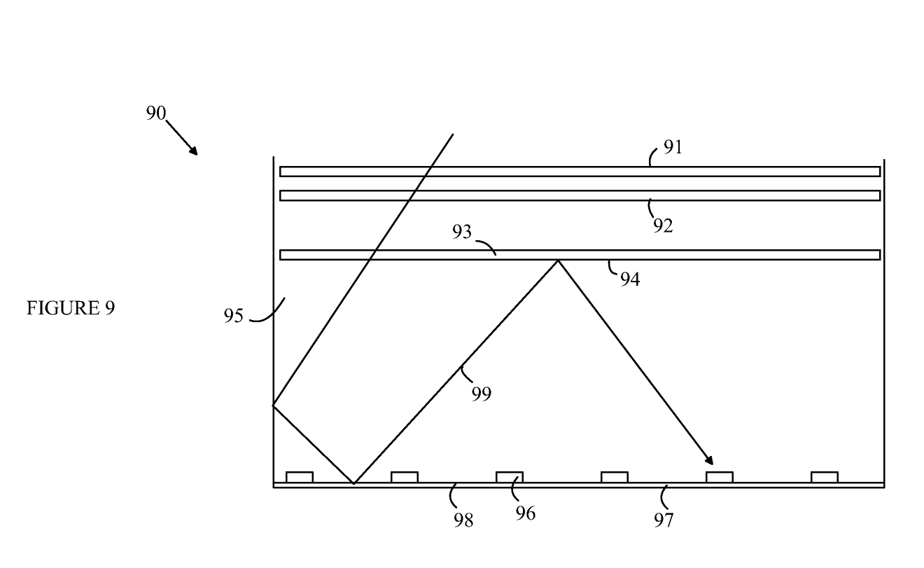

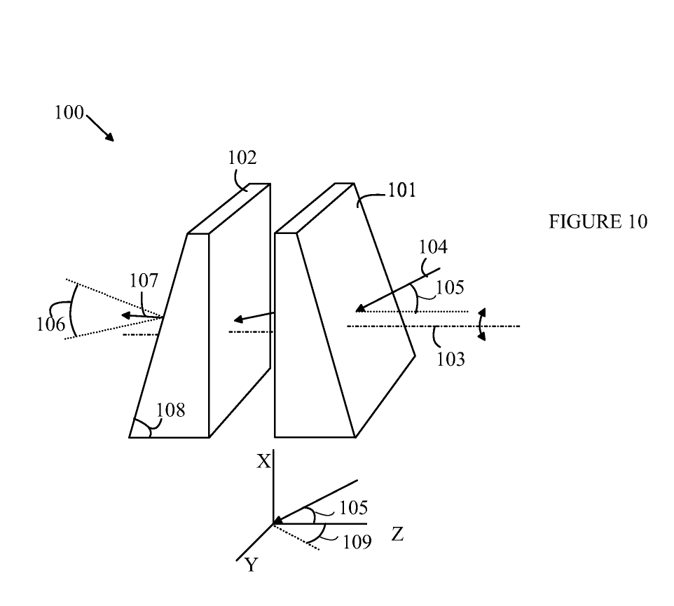

In one aspect of the invention, the beam steering assemblies in multiple power modules in a close-packed array are driven by two drive shafts connected to corresponding actuators. Refer now to FIGS. 5-7, which illustrate an array of power modules according to one embodiment of the present invention. FIG. 5 is a top view of array 60; FIG. 6 is a partial cross-sectional view through line 6-6 shown in FIG. 5, and FIG. 7 is a partial cross-sectional view through line 7-7 shown in FIG. 5. Power module array 60 includes a plurality of power modules that are driven by two drive shafts. Exemplary power modules are shown at 61-64. Drive shaft 68 is driven by actuator 66, and drive shaft 65 is driven by actuator 67. Drive shaft 68 moves the upper beam steering element 71 in each power module, and drive shaft 65 moves the lower beam steering element 72 in each power module.

The drive shafts engage worm gears on the beam steering elements. Drive shaft 68 engages worm gears 74 and 76, and drive shaft 65 engages worm gears 75 and 77. The worm gears for beam steering elements on one side of a drive shaft have the opposite handedness from those on the other side of that drive shaft. For example, worm gear 74 could utilize a right hand screw, and worm drive 76 would then utilize a left hand screw. The worm gears engage structures on the surface of the beam steering elements that cause the beam steering elements to rotate about axis 73. By utilizing drives with opposite handedness, two drives can operate all of the beam steering elements.

Hence, the only difference between the power modules is the location of the worm drive and the handedness of the screw within it. The Fresnel lens arrays 78 and PV cell containing substrate 79 remain the same in both types of power modules.

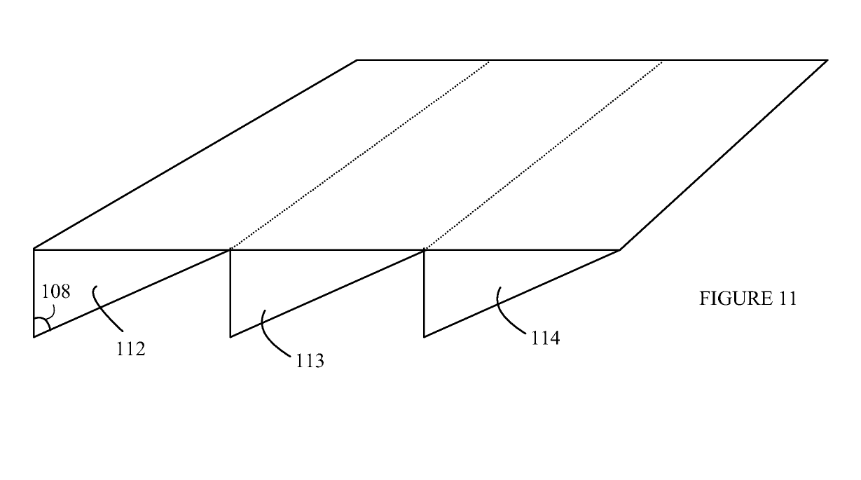

In one aspect of the invention, the power modules are packaged in hexagonal housings that include external couplings for the drive shafts discussed above. Refer now to FIG. 8, which is a top view of an array of packaged power modules that utilize hexagonal housings. Array 80 includes 10 power modules 81 that are closely packed with a pair of drive shafts 82 that traverse each power module. The actuators for the power modules are shown at 83 and 84. Since hexagons tile a surface, the loss in efficiency is limited to the difference in area between the circular beam steering elements and the hexagon housing and the area needed for the actuators.

Fresnel reflections resulting from the difference of index of refraction between the materials from which the beam steering elements and Fresnel lenses are made and air can result in significant loss of light, and hence, reduce the overall efficiency of the power modules. Coating the surfaces of these optical elements with anti-reflection coatings reduces such reflections; however, the cost of the power modules is increased because of the additional fabrication steps inherent in applying the coatings and the cost of the coating materials.

An alternative approach to providing anti-reflective surfaces involves texturing the surfaces to provide a region of graded index of refraction. If the surface is roughened by introducing features that are much smaller than the wavelength of light that is incident on the surface, the light will not be scattered. Instead, the light perceives a surface that has an index of refraction that changes gradually from that of air to that of the material from which the surface is constructed. This gradual increase in index of refraction reduces Fresnel reflections, and hence, reduces light losses that would otherwise decrease the efficiency of the power module.

The surface roughening can be accomplished by ion etching the surface or by molding the texture into the surface. In the case of molding or embossing, the texture is provided in the mold or the embossing head by etching the mold or embossing head surface. Hence, this technology is particularly attractive for providing an anti-reflective surface on a part that is already being molded or embossed.

Alternatively, the surface of the embossed or molded optical element can be roughened by etching during the roll-to-roll processing steps in which the other optical features are embossed into the films. For example, a planar master Fresnel prism array is created in acrylic and exposed to a low energy ion beam to impart the anti-reflective structure on the prism profile. Next, this master is plated with metal which is subsequently wrapped around a cylinder for the roll-to-roll manufacturing process. Thereafter, an acrylic resin is deposited on a carrier film (e.g., polyethylene terephthalate (PET)), which is subsequently fed into the aforementioned roller with the requisite micro-prism/anti-reflection profile. The resin (now imprinted with the profile) is subsequently UV cured in contact with the roller.

Thermal embossing may also be employed. In this application, a polymer film is heated and passed under the aforementioned cylinder. The polymer flows into the groove profile of the cylinder reproducing the microstructure and the anti-reflection structure.

In general, anti-reflective coatings based on roughening the surface of the optical elements that are subject to such reflection are not used in solar systems because the surface is easily damaged during cleaning or when subjected to environmental abrasion from wind-carried dust particles. However, in the present invention, the beam steering elements and Fresnel lens array are protected from the environment by the outer housing in which the power modules are mounted, and hence, these elements are protected from the elements and do not need frequent cleaning. The remaining optical losses from the system arise from the cover glass. Conventional, high durability, low cost anti-reflective coatings, such as those produced by Xerocoat Inc., may be used to minimize Fresnel losses arising at the cover glass.

A significant fraction of the light that reaches the power modules is light that is scattered in the atmosphere, and hence, is not focused onto the PV cells by the beam steering assembly and the concentrators. Some light will be trapped in the optical elements by internal reflection and escape at angles and locations such that this light is not concentrated on the PV cells. Some of this non-collimated light will be received by the PV cells and be converted to electricity; however, since the fraction of the substrate area that is covered by PV cells is roughly proportional to one over the concentrator factor; hence, little power is gained from that light absent some mechanism to increase the amount of this light that hits the PV cells.

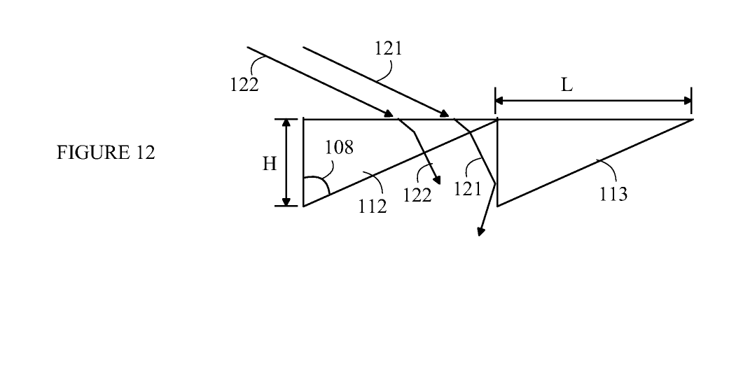

Refer now to FIG. 9, which is a cross-sectional view of a power module 90 according to another embodiment of the present invention. Power module 90 is similar to the embodiments discussed above in that power module 90 includes two beam steering elements 91 and 92 which direct light onto an array of Fresnel lenses 93 at angles within a small cone of angles such that the light is then concentrated on PV cells 96. As noted above, it is advantageous to utilize a Fresnel lens in which the structure is on the top surface of the lens. Such lenses are not normally used in PV systems because of the problems encountered in cleaning the lenses. The present invention has significantly less problems in this regard, and hence, lens array 93 has the features on the top surface. The bottom surface of lens array 93 is not coated with an anti-reflective coating and is planar. Hence, light striking that surface from below will be subjected to significant Fresnel reflections if the angle of incidence is sufficiently large.

In this aspect of the invention, light trapped beneath lens array 93 in cavity 95 is recycled until it strikes a PV cell or is lost. The walls of the cavity defined by lens array 93, the housing and the substrate 97 are coated with a reflective material that scatters any light striking those surfaces. Hence, a significant fraction of the ambient light will be trapped in this cavity by reflections from the bottom surface of lens array 94 or by reflections/scattering from the walls. Consider the light ray shown at 99. This light originates outside of module 90 as ambient light that is not concentrated by the optics. The light ray strikes the side of the housing where it is reflected to a point between the PV cells. The reflective surface between the cells redirects the light back toward lens array 93 where it reflected from bottom surface 94 back toward the PV cells. The light will either hit a PV cell or be again reflected from the area between the cells. In this manner, ambient light is recycled until it is finally absorbed, hits a PV cell, or escapes by striking surface 94 at an angle close to the normal to that surface.

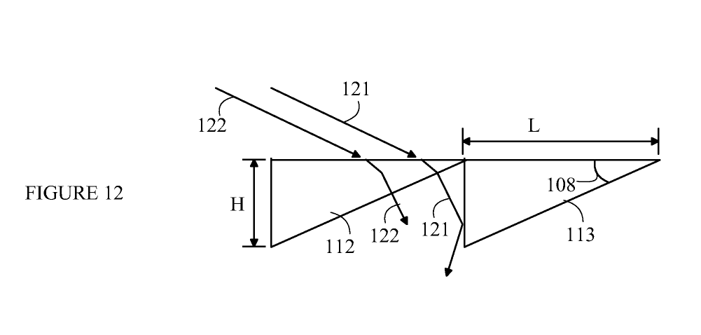

The above-described embodiments utilize a beam steering assembly based on arrays of micro-prisms. The manner in which these arrays are constructed can be more easily understood with reference to Risley prism based beam steering systems. Since such systems are known to the art, they will not be discussed in detail here. For the purposes of this discussion, a Risley prism beam steering system consists of two prisms that are rotated with respect to one another. Refer now to FIG. 10, which illustrates a beam steering assembly based on two such prisms. Beam steering assembly 100 is constructed from two rectangular prisms 101 and 102. The prisms are mounted such that the prisms can be rotated with respect to one another about axis 103. To simplify the drawing, the mounting and rotational structures have been omitted.

Consider an input light beam 104. The angle of entry into prism 101 is characterized by two angles in polar coordinates relative to the XYZ-coordinate system shown in the figure. In general, there is a rotation of the prism 101 with respect to prism 102 and a rotation of prism 101 relative to the coordinate system such that a light beam 104 that enters prism 101 at angles 105 and 109 will exit prism 102 within a cone of angles 106 about axis 103 for any value of angle 105. Conversely, given angle 105, the rotational angle of prism 102 relative to 101 can be determined from geometric optics such that the angle of ray 107 with respect to axis 103 is minimized. In general, the minimum angle is not zero for all possible angles 105. The variation in angle is bounded by cone 106.

The size of cone 106 depends on the angle 108 in the prisms. As the angle is increased, angle 106 is reduced at the expense of increasing the size of the prisms. In principle, a beam steering assembly can be constructed by mounting prisms 101 and 102 on transparent disks that rotate about an axis that is parallel to the optical axis of the concentrator in the power cell. Angle 108 would then be chosen such that angle 106 is within the acceptance angle of the concentrator. It should be noted that the acceptance angle of the concentrator is typically a function of the maximum concentration factor provided by the concentrator. While a beam steering assembly can be constructed in this manner, the cost and weight of the beam steering assembly for a typical solar power application would be prohibitive.

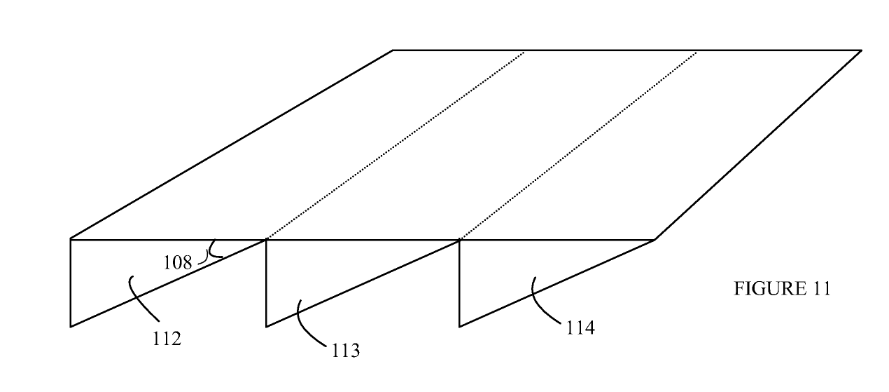

To reduce the mass of the beam steering assembly, the present invention breaks up the large prisms into a plurality of smaller prisms in a manner analogous to that utilized in creating a Fresnel lens from a conventional lens. Refer now to FIG. 11, which illustrates the manner in which a large prism is broken up into three smaller prisms shown at 112-114.

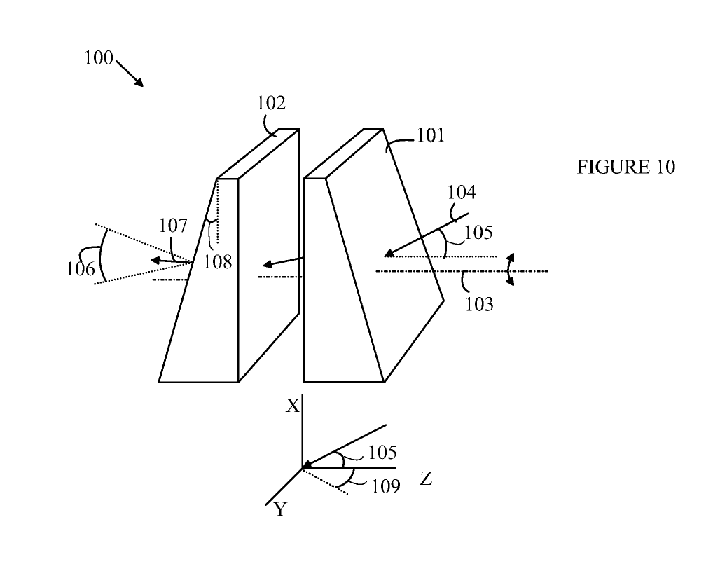

Fresnel prism arrays have well understood optical loss mechanisms. Refer now to FIG. 12, which is a cross-sectional view through a portion of a Fresnel prism array. Ray 122 is bent by prism 112 and leaves the array without encountering any other facets in the array. Ray 121, in contrast, strikes the vertical facet of prism 113 and is reflected to a new angle. Hence, ray 122 will not be properly steered by the second prism array in the beam steering assembly if this prism array is the first of the two beam steering elements through which the light passes. It should be noted that if the prism array in FIG. 13 were the second of the two prisms, the rays leaving the prism array might fall within the cone of angles discussed above with respect to the normal to the top surface, and hence, the number of rays that have aberrant interactions can be much smaller in the second beam steering element.

The losses in a Fresnel prism array depends on the parameters L and H shown in FIG. 13. Increasing L for a fixed value of H reduces the fraction of the rays such as ray 121 that undergo unwanted reflections. As noted above, angle 108 determines the cone of angles of the final steered rays. Increasing angle 108 increases L for a given value of H; however, there is a limit on angle 108 that is set by the acceptance angle of the concentrators. In one preferred embodiment, the concentrators are two dimensional concentrators and provide a factor of 50 concentration. Such concentrators have an acceptance angle of ±8 degrees for a PV cell in air. This acceptance angle increases to ±12 degrees if the PV cell is optically contacted to a higher index of refraction media as is the case when a secondary optical element is employed. Hence, angle 108 must be set to provide a cone of exit angles that is no greater than ±8 degrees. The exact value of angle 108 will depend on the index of refraction of the material from which the Fresnel prism array is constructed. Hence, to increase L further beyond the values that provide an acceptable cone of angles from the beam steering assembly, H must be increased. The maximum value of H is set by the manufacturing process. If the optical features are created by thermal embossing in a roll-to-roll process, H is typically less than 200 microns.

Given H, L can be determined. Referring to FIG. 3, the upper sheet 56 prism angle must be less than the total internal reflection (TIR) angle. In the case of acrylic with index 1.49, The TIR angle is 42.2°. The upper prism should be a few degrees less than this angle to minimize Fresnel reflections that increase as the TIR angle is approached (37-40°. The lower prism angle is chosen to maximize the functional field of view and the optical throughput of the beam steering assembly. In the case where the upper prism angle is chosen to be 38°, the lower prism angle is optimally determined to be approximately 56.5° for a 50×2-D concentrator system.

The above-described embodiments refer to optical concentrators. For the purposes of this discussion, a light concentrator is defined to be an optical element that receives light at a first optical power density over an input aperture (typically the diameter of that optical element) and operates on that light so that it emerges from the concentrator at a higher optical power density through an output aperture that is smaller than the input aperture. For example, referring to FIG. 1, the input aperture is the diameter of lens 24. The output aperture of the concentrator may be taken to be the diameter of corresponding light receiver 25, which is placed such that the light from lens 24 covers the light receiver. Light concentrators can be constructed from imaging optical elements such as lens and parabolic reflectors or non-imaging elements such as compound parabaloids.

It should be appreciated that the films may include feature shapes other than prisms to accomplish the required optical processing.

The Summary of the Invention and the above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

What is claimed is:

1. An apparatus comprising:
a beam steering assembly that directs light traveling in a first direction to light traveling in a second direction;
a plurality of converters, each converter being fixed with respect to a substrate, and each converter comprising a light concentrator and a receiver, said light concentrator receiving light from said second direction at a first optical power density and generating a light beam on said receiver at a second optical power density that is greater than said first optical power density, said light receiver converting said received light to electricity;
a controller that determines the position of the sun relative to said beam steering assembly and controls said beam steering assembly such that said concentrators receive sunlight from that determined direction,
wherein each light concentrator is fixed relative to said light receiver that receives light from that light concentrator, and
wherein said beam steering assembly moves relative to said substrate.

2. The apparatus of claim 1 wherein said beam steering assembly comprises first and second beam steering elements, each beam steering element moving relative to said substrate.

3. The apparatus of claim 2 wherein said first and second beam steering elements each comprise a transparent beam steering sheet having optical processing features thereon, said first and second beam steering elements rotating independently with respect to said substrate about a common axis in response to commands from said controller.

4. The apparatus of claim 3 wherein said optical processing features of said beam steering sheet are micro-prisms.

5. The apparatus of claim 3 wherein at least one of said first and second beam steering sheets has a surface that is textured with an anti-reflective structure.

6. The apparatus of claim 2 wherein each of said plurality of light concentrators is included in a transparent concentrating sheet comprising all the other of said plurality of light concentrators, said concentrating sheet having optical processing features thereon.

7. The apparatus of claim 6 wherein said concentrating sheet comprises a Fresnel lens array.

8. The apparatus of claim 6 wherein said top surface of said concentrating sheet receiving light traveling in said second direction from said beam steering assembly includes said optical processing features of said concentrating sheet.

9. The apparatus of claim 6 wherein a surface of said concentrating sheet is textured with an antireflective nano-structure.

10. An apparatus comprising:
a plurality of power modules, each power module comprising:
a beam steering assembly that directs light traveling in a first direction to light traveling in a second direction, said beam steering assembly comprising first and second beam steering elements, each beam steering element rotating about a common rotational axis; and
a plurality of converters, each converter being fixed with respect to said substrate, and each converter converting light from said beam steering assembly traveling in said second direction to electricity;
first and second drive shafts coupled to said first and second beam steering elements, respectively, said first and second drive shafts causing said first or said second beam steering elements, respectively, of each power module to rotate about said rotation axis of that power module; and
a controller that determines a direction for the sun and controls said first and second drive shafts such that said converters receive sunlight from said second direction.

11. The apparatus of claim 10 further comprising first and second actuators coupled to said first and second drive shafts to turn said first and second drive shafts in response to commands from said controller.

12. The apparatus of claim 10 wherein said first and second beam steering elements of each power module each comprise a transparent beam steering sheet having optical processing features thereon.

13. The apparatus of claim 12 wherein said optical processing features of said beam steering sheets are micro-prisms.

14. The apparatus of claim 12 wherein one of said first and second beam steering sheets has a surface that is textured with an antireflective nano-structure.

15. The apparatus of claim 10 wherein each of said plurality of light concentrators in each of said power modules is included in a transparent concentrating sheet comprising all the other of said plurality of light concentrators.

16. The apparatus of claim 15 wherein each of said concentrating sheets in each of said power modules comprises a Fresnel lens array.

17. The apparatus of claim 15 wherein a surface that receives light traveling in said second direction from said corresponding beam steering assembly includes said optical processing features of that concentrating sheet.

18. The apparatus of claim 15 wherein a surface of each of said concentrating sheets is textured with an anti-reflective nano-structure.

19. A method for converting the captured light to electricity, said method comprising:
providing a beam steering assembly comprising first and second beam steering elements, each beam steering element moving relative to a substrate that is fixed relative to the surface of the earth;
directing light traveling in a first direction to light traveling in a second direction using said beam steering assembly;
converting light to electricity using a plurality of converters and a corresponding plurality of receivers, each converter being fixed with respect to said substrate, and each converter comprising a concentrator concentrating light received from said second direction onto a corresponding receiver, said receiver converting said received light to electricity, wherein each light concentrator is fixed relative to said receiver that receives light from that light concentrator; and
determining a direction of the sun relative to said beam steering assembly and altering said first direction such that said concentrators receive light from that direction.

20. The method of claim 19 wherein providing said beam steering assembly comprises imprinting micro-prisms onto a surface of each of said first and second beam steering sheets.
